(19) United States
(12) Patent Application Publication
(10) Pub. No.: US 2017/0215278 A1
(43) Pub. Date: Jul. 27, 2017

(54) CORELESS SUBSTRATE HAVING PRIMER LAYERS ADJACENT TO BOTTOM AND TOP OUTER METAL LAYERS

(71) Applicant: Avago Technologies General IP (Singapore) Pte. Ltd., Singapore (SG)

(72) Inventors: Padam Jain, Castro Valley, CA (US); Sarah Haney, San Jose, CA (US); Lea-Teng Lee, Sunnyvale, CA (US)

(21) Appl. No.: 15/008,137

(22) Filed: Jan. 27, 2016

(51) Int. Cl. H05K 1/03; H05K 3/46; H05K 3/06; H05K 1/09

(52) U.S. Cl. CPC H05K 1/0353; H05K 1/09; H05K 3/4611; H05K 3/06

(57) ABSTRACT

A coreless substrate of a printed circuit board is provided. The coreless substrate includes a first outer metal layer; a first primer layer formed on the first outer metal layer; a first layer of functional prepreg material formed on the first primer layer; a second primer layer formed over the first layer of functional prepreg material; and a second outer metal layer formed on the second primer layer. The first outer metal layer corresponds to a first outer most surface of the printed circuit board, and the second outer metal layer corresponds to a second outer most surface of the printed circuit board.

### BACKGROUND

There is increasing demand for smaller electronic devices, particularly with respect to radio frequency (RF) wireless communication products, for example. These products include electrical circuitry comprising various components, such as resistors, capacitors, inductors, amplifiers, filters and the like, which are typically provided by printed circuit boards (PCBs) incorporated into the products.

In order to minimize dimensions and maximize use of available space, PCBs typically have substrates formed of multiple layers with electrical circuitry formed between and within the layers. The layers may be formed of “prepreg” material, which generally includes a base material, such as glass fabric impregnated with resin. The prepreg material layers are commonly applied to structural cores or carriers to provide the multi-layered PCBs. In a coreless manufacturing process, the prepreg material layers are eventually detached from the core after a certain number of metal layers, including patterned metal layers, have been added between the prepreg material layers (e.g., to provide fine traces and other electrical circuitry), and a symmetrical build-up is continued without the core for high layer count PCBs. In this case, the detach structure, consisting of layers of prepreg and metal, provide structural support in the absences of the core. Generally, prepreg-based coreless substrates provide a desirable balance between the package thickness reduction and thermo-mechanical stability.

With the continuous demand of functional integration in RF products, design feature scaling is required, and may be achieved in part using a primer based semi-additive patterning (PSAP) process. However, the PSAP process is not available for the starting (bottom) metal layer (layer adjacent to the carrier) of a coreless prepreg manufacturing process since there is no primer layer adjacent to the bottom metal layer, preventing fine traces and circuitry on the bottom metal layer. Alternatives for fine traces can be embedded traces, which reduce the need for additional prepreg and metal layers, but embedded traces increase production lead time, which is critical for products in mobile applications.

Proposed solutions also provide warpage benefits in the symmetric build-up of prepreg-based coreless substrates. Without the proposed solutions, an outer metal layer on one side of the substrate is embedded, resulting in a significant dielectric resin volume imbalance resulting in warpage issues.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements throughout the drawings and written description.

FIG. 1 is simplified cross-sectional view of a multi-layer coreless substrate of a printed circuit board (PCB) post detach, having top and bottom outer metal layers with adjacent primer layers, according to a representative embodiment.

FIG. 2 is simplified cross-sectional view of a preformed sheet, having metal and primer layers, which may be incorporated into the coreless substrate of FIG. 1, according to a representative embodiment.

FIGS. 3A to 3G are simplified cross-sectional views showing an illustrative method of fabricating a multi-layer coreless substrate of a PCB, according to a representative embodiment.

FIGS. 4A to 4G are simplified cross-sectional views showing a conventional method of fabricating a multi-layer coreless substrate of a PCB, for purposes of comparison.

### DETAILED DESCRIPTION

In the following detailed description, for purposes of explanation and not limitation, example embodiments disclosing specific details are set forth in order to provide a thorough understanding of the present teachings. However, it will be apparent to one of ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms “a”, “an” and “the” include both singular and plural referents, unless the context clearly dictates otherwise. Thus, for example, “a device” includes one device and plural devices. The terms “substantial” or “substantially” mean to within acceptable limits or degree. The term “approximately” means to within an acceptable limit or amount to one of ordinary skill in the art. Relative terms, such as “above,” “below,” “top,” “bottom,” “upper” and “lower” may be used to describe the various elements” relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Where a first device is said to be connected or coupled to a second device, this encompasses examples where one or more intermediate devices may be employed to connect the two devices to each other. In contrast, where a first device is said to be directly connected or directly coupled to a second device, this encompasses examples where the two devices are connected together without any intervening devices other than electrical connectors (e.g., wires, bonding materials, etc.).

In various representative embodiments, a coreless multi-layered PCB and a method for fabricating the coreless multi-layered PCB are provided, which involve innovative stacking of an organic core, a non-functional prepreg material, and metal layers with corresponding primer material. Generally, to provide an alternative lamination stack-up for the first metal layer of the PCB, an organic core material will be used rather than a conventional “off-the-shelf” carrier material with peelable copper foil. A layer of inexpensive non-functional prepreg material is stacked on the core material, followed by stacking of copper foil coated with primer material, which includes a carrier copper foil, as well. Stacking (or build-up) continues with a layer of functional prepreg material and an additional layer of primer material. Both layers of primer material face the layer of functional prepreg material. This stack is laminated through a hot press. The remainder of the process may follow traditional manufacturing steps. Accordingly, fine lines and space for routing are available in all the layers of the prepreg coreless substrate with the minimal processing time and steps. Also, the warpage risk is minimized in the sequentially built-up prepreg-based coreless substrate.

According to a representative embodiment, a coreless substrate of a PCB is provided. The coreless substrate includes a first outer metal layer corresponding to a first outer most surface of the coreless printed circuit board, post detach process; a first primer layer formed on the first outer metal layer; a first layer of functional prepreg material formed on the first primer layer; a second primer layer formed over the first layer of functional prepreg material; and a second outer metal layer formed on the second primer layer, the second outer metal layer corresponding to a second outer most surface of the PCB.

According to another representative embodiment, a coreless substrate of a laminated PCB is provided. The coreless substrate includes a first outer metal layer providing a first outer most surface of the PCB; a first primer layer disposed adjacent to the first outer metal layer; a first layer of functional prepreg material disposed adjacent to the first primer layer; a second outer metal layer providing a second outer most surface of the printed circuit board, opposite the first outer most surface; a second primer layer disposed adjacent to the second outer metal layer; a second layer of functional prepreg material disposed adjacent to the second primer layer; and at least one buried patterned metal layer and a corresponding at least one buried intermediate primer layer positioned between the first and second layers of the functional prepreg material.

According to another representative embodiment, a method is provided for fabricating a coreless substrate. The method includes providing an organic carrier layer; applying a layer of non-functional prepreg material to the organic carrier layer; applying a stack of a first carrier metal layer, a first release layer, a first metal layer, and a first primer layer to the layer of non-functional prepreg material; applying a first layer of functional prepreg material to the first primer layer; applying an inverted stack of a second carrier metal layer, a second release layer, a second metal layer and a second primer layer to the first layer of functional prepreg material; removing the second carrier metal layer and the release layer from the inverted stack; and removing the second metal layer to expose the second primer layer. The method further includes applying a metal layer to the exposed second primer layer, and patterning the metal layer to form a first patterned metal layer; applying a second layer of functional prepreg material over the first patterned metal layer; applying a third primer layer over the second layer of functional prepreg material; applying a third metal layer on the third primer layer; and removing the organic carrier layer, the layer of non-functional prepreg material, the first carrier layer and the first release layer from the first metal layer, resulting in the first metal layer and the third metal layer being outer most surfaces of the coreless substrate, respectively.

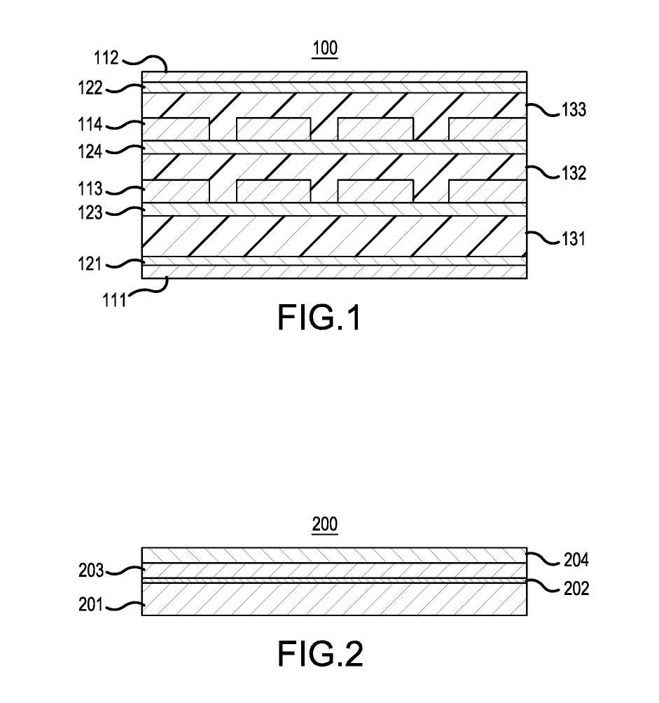

FIG. 1 is simplified cross-sectional view of a multi-layer coreless substrate of a post detach PCB, having top and bottom outer metal layers with adjacent primer layers, according to a representative embodiment.

Referring to FIG. 1, coreless substrate 100, which may or may not continue with the symmetric build depending on layer count requirements includes a first (bottom) outer metal layer 111, which may correspond to a first (bottom) outer most surface of the coreless substrate 100, and a first primer layer 121 on the first outer metal layer 111. In an embodiment, the first outer metal layer 111 may be formed of copper (Cu) foil at a thickness of approximately 2 μm, for example. However, other metals compatible with semiconductor processes, such silver (Ag), gold (Au) and/or aluminum (Al), for example, as well as other thicknesses (e.g., in a range of approximately 5 μm to approximately 20 μm may be incorporated without departing from the scope of the present teachings.

The first primer layer 121 provides fine line and space enabling surface and adhesion of the first outer metal layer 111 to the next adjacent layer (e.g., a first layer of functional prepreg material 131) of the coreless substrate 100. In an embodiment, the first primer layer 121 is formed of an epoxy resin at a thickness of approximately 2 μm, for example, although other dielectric materials compatible with semiconductor processes, such as a polymer or another type of resin, may be incorporated without departing from the scope of the present teachings. In an embodiment, a surface of the first outer metal layer 111 contacting the first primer layer 121 is smoother than an opposite surface of the first outer metal layer 111.

The coreless substrate 100 further includes various multiple substrate layers, including layers functional prepreg material (e.g., first layer of functional prepreg material 131, second layer of functional prepreg material 132 and third layer of functional prepreg material 133), buried intermediate primer layers (e.g., second primer layer 122, third primer layer 123 and fourth primer layer 124), and buried patterned metal layers (first patterned metal layer 113 and second patterned metal layer 114), arranged between the first outer (bottom) metal layer 111 and a second outer (top) metal layer 112, where the second outer metal layer 112 may correspond to a second (top) outer most surface of the coreless substrate 100. The first and second outer most surfaces of the coreless substrate 100 (e.g., first and second outer metal layers 111 and 112) are symmetric, in that they are adjacent to corresponding primer layers (e.g., first and second primer layers 121 and 122), respectively.

Like the first outer metal layer 111 discussed above, the second outer metal layer 112 may be formed of copper (Cu) foil at a thickness of approximately 2 μm, for example, although other materials and/or thicknesses may be incorporated without departing from the scope of the present teachings. The second primer layer 122 provides fine line and space enabling surface and adhesion. Like the first primer layer 121 discussed above, the second primer layer 122 is formed of an epoxy resin at a thickness of approximately 2 μm, for example, although other materials and/or thicknesses may be incorporated without departing from the scope of the present teachings.

Also, as mentioned above, the presence of primer layers (e.g., first and second primer layers 121 and 122) adjacent to both outer metal layers (e.g., first and second outer metal layers 111 and 112) enables continuation of a symmetric build-up on the top and bottom outer surfaces of the PCB due to the availability of a primer layer on both sides of the coreless substrate 100, including addition of surface mounted technology (SMT), if desired.

With respect to the intermediate layers in the depicted embodiment, arranged between the first and second primer layers 121 and 122, the first layer of functional prepreg material 131 is formed on the first primer layer 121, the third primer layer 123 is formed on the first layer of functional prepreg material 131, the first patterned metal layer 113 is formed on the third primer layer 123, and the second layer of functional prepreg material 132 is formed on the first patterned metal layer 113 and portions of the third primer layer 123. Further, the fourth primer layer 124 is formed on the second layer of functional prepreg material 132, the second patterned metal layer 114 is formed on the fourth primer layer 124, and the third layer of functional prepreg material 133 is formed on the second patterned metal layer 114 and portions of the fourth primer layer 124. Of course, the number of intermediate layers may vary to provide unique benefits for any particular situation or to meet application specific design requirements of various implementations, as would be apparent to one skilled in the art.

In various embodiments, each of the first through third layers of functional prepreg material 131-133 provides structural support and electrical isolation, and may be formed of glass fabric impregnated with resin, for example, although other materials or combinations of materials may be incorporated without departing from the scope of the present teachings. Each of the first and second patterned metal layers 113 and 114 provides at least a portion of internal circuitry accommodating the electrical circuitry for which the PCB is designed. Various arrangements of traces, vias, terminals, ground planes and other electrical circuitry may be included to provide unique benefits for any particular situation or to meet application specific design requirements of various implementations, as would be apparent to one skilled in the art. The first and second patterned metal layers 113 and 114 may be formed of any metal(s) compatible with semiconductor processes, such copper (Cu), silver (Ag), gold (Au) and/or aluminum (Al), for example, at various thicknesses and having various layouts, as would be apparent to one of ordinary skill in the art. The material(s) and/or thickness(es) of the first and second patterned metal layers 113 and 114 may be the same as or different from those of the first and second outer metal layers 111 and 112, and likewise may be the same as or different from one another, without departing from the scope of the present teachings. The third and fourth primer layers 123 and 124 may be substantially the same as the first and second primer layers 121 and 122, described above, except located adjacent patterned metal layers (e.g., first and second patterned metal layers 113 and 114) as opposed to outer metal layers (e.g., first and second outer metal layers 111 and 112).

In an embodiment, each of the paired first outer metal layer 111 and first primer layer 121 and the paired second outer metal layer 112 and second primer layer 122 may be provided by a preformed sheet of metal/primer layers, such as PF-EL, available from Hitachi Chemical Co., for PCB fabrication. For example, FIG. 2 is simplified cross-sectional view of such a preformed sheet, having metal and primer layers, which may be incorporated into the coreless substrate 100. In the depicted example, preformed sheet 200 includes carrier metal (e.g., foil) layer 201, release layer 202, primer coated metal (e.g., foil) layer 203 and primer layer 204. The carrier metal layer 201 and the primer coated metal layer 203 each may be formed of a copper (Cu) foil, and the release layer 202 may be formed of an adhesive material, for example. The release layer 202 enables easy removal of the carrier metal layer 201 from the primer coated metal layer 203 after application of the preformed sheet 200 to the stack that ultimately forms the coreless substrate 100.

For example, in an embodiment, the preformed sheet 200 may be inverted and applied to the third layer of functional prepreg material 133, where the primer layer 204 (e.g., corresponding to the second primer layer 122 in FIG. 1) adheres to the third layer of functional prepreg material 133. The carrier metal layer 201 may then be peeled away via the release layer 202, leaving the primer coated metal layer 203 (e.g., corresponding to the second outer metal layer 112 in FIG. 1) exposed. Likewise, the preformed sheet 200 may be applied to a non-functional prepreg layer (not shown in FIG. 1), discussed below, where the carrier metal layer 201 adheres to the non-functional prepreg layer. The carrier metal layer 201 may then be peeled away via the release layer 202, leaving the primer coated metal layer 203 (e.g., corresponding to the first outer metal layer 111 in FIG. 1) exposed, and the primer layer 204 (e.g., corresponding to the first primer layer 121 in FIG. 1) already formed on the primer coated foil.

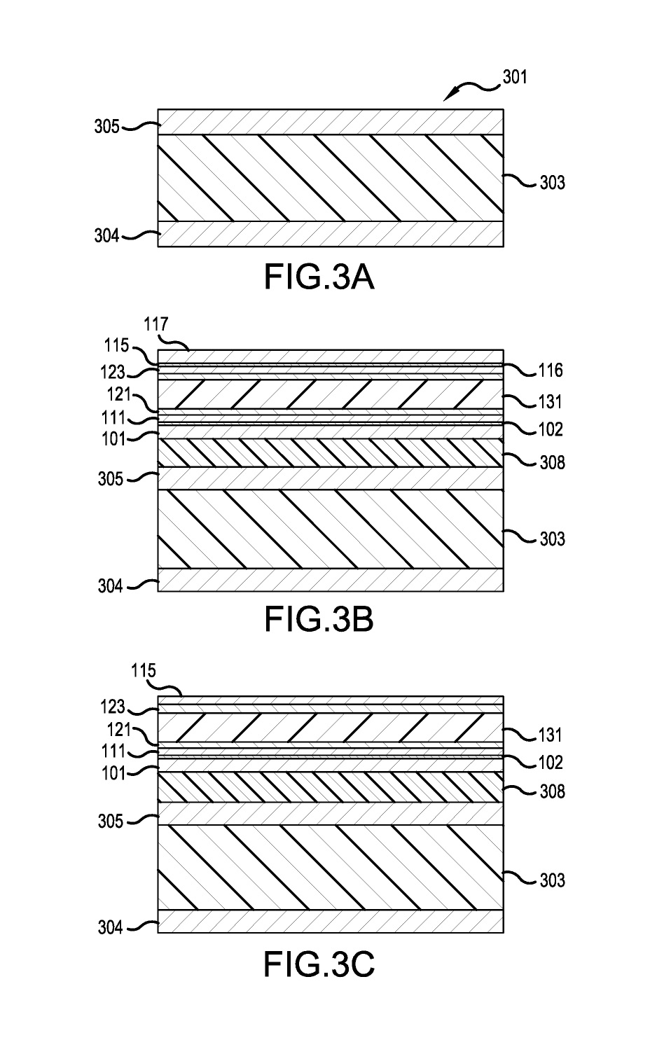

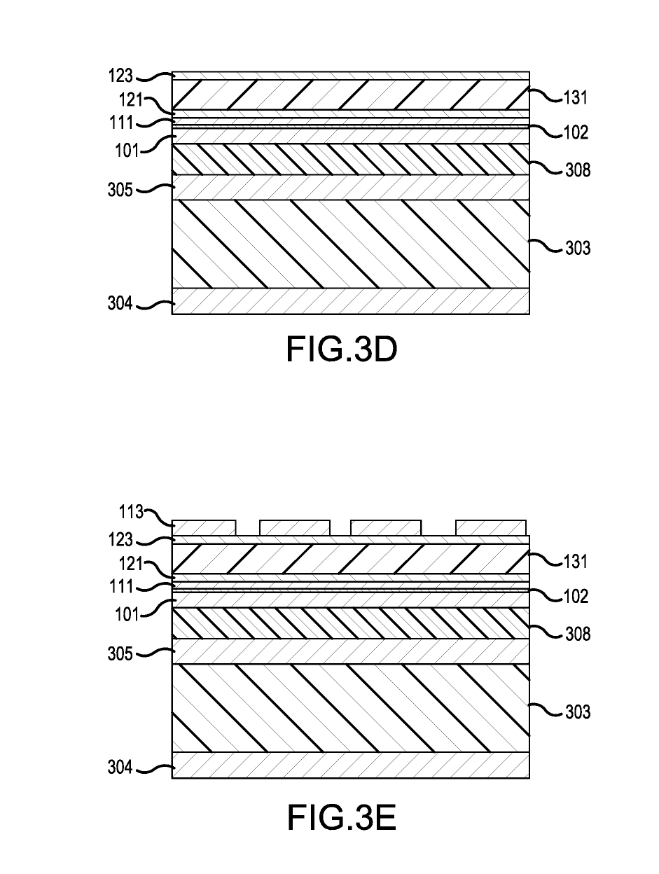

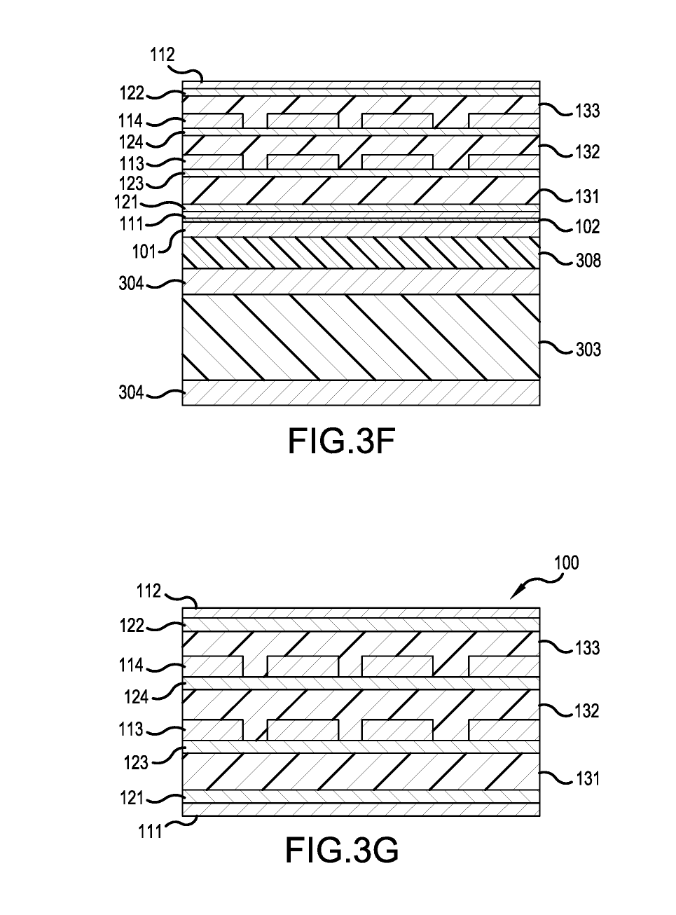

FIGS. 3A to 3G are simplified cross-sectional views showing an illustrative method of fabricating a multi-layer coreless substrate of a PCB, according to a representative embodiment.

Referring to FIG. 3A, a detachable core 301 is provided. In the depicted embodiment, the detachable core 301 is a copper clad laminate (CCL) comprising an organic core layer 303 between first and second copper layers 304 and 305. The organic core layer 303 may be formed of glass fabric impregnated in resin for example, although other materials may be incorporated as the organic core layer 303 and/or as the cladding metal, without departing from the scope of the present teachings. The detachable core 301 may be a preformed component.

In FIG. 3B, an initial stack-up is formed on the second copper layer 305 for hot press lamination. More particularly, a layer of non-functional prepreg material 308 is applied to the second copper layer 305. The non-functional prepreg material 308 may be a dielectric material, such as glass fabric impregnated in resin or any other adhesive material, for example, and provides adhesion, separation and isolation from the second copper layer 305 of the detachable core 301 to enable fabrication of the coreless substrate 100. A first carrier metal layer 101, a first release layer 102, the first outer metal layer 111, and the first primer layer 121 are stacked on the layer of non-functional prepreg material 308, and the first layer of functional prepreg material 131 is applied to the first primer layer 121. In an embodiment, the stack including the first carrier metal layer 101, the first release layer 102, the first outer metal layer 111 and the first primer layer 121 may be implemented, for example, using the preformed sheet 200 discussed above with reference to FIG. 2. That is, the carrier metal layer 201 may provide the first carrier metal layer 101; the release layer 202 may provide the first release layer 102; the primer coated metal layer 203 may provide the first outer metal layer 111; and the primer layer 204 may provide the first primer layer 121.

Referring again to FIG. 3B, the third primer layer 123, a temporary metal layer 115, a second release layer 116 and a second carrier metal layer 117 are then stacked on the first layer of functional prepreg material 131. In an embodiment, the stack including the third primer layer 123, the temporary metal layer 115, the second release layer 116 and the second carrier metal layer 117 may likewise be implemented, for example, using the preformed sheet 200 (inverted) discussed above with reference to FIG. 2. That is, the carrier metal layer 201 may provide the second carrier metal layer 117; the release layer 202 may provide the second release layer 116; the primer coated metal layer 203 may provide the temporary metal layer 115; and the primer layer 204 may provide the third primer layer 123. The detachable core 301 and the layers stacked thereon are then laminated using a hot press, for example. Of course, other implementations may be incorporated without departing from the scope of the present teachings.

The second carrier metal layer 117 is peeled away via the second release layer 116, as shown in FIG. 3C, exposing the temporary metal layer 115. Removing the second carrier metal layer 117 from the temporary metal layer 115 may include a decarrier or depanel process. The temporary metal layer 115 is removed, as shown in FIG. 3D, exposing the third primer layer 123. The temporary metal layer 115 may be removed using a chemical etching process, for example.

In FIG. 3E, the first patterned metal layer 113 is formed on the exposed third primer layer 123. The first patterned metal layer 113 may be formed by applying a metal layer to the third primer layer 123 using chemical solutions or other metal deposition methods for example, and covering the metal layer with an etch mask formed of an etch resistant material corresponding to the desired pattern. The metal layer may then be etched through the etch mask using a wet etching process, for example, to form the first patterned metal layer 113. Alternatively, the patterning may be performed using a photolithography process to define a mask pattern, and etching the metal layer using the mask pattern. Of course, any compatible etching process may be incorporated without departing from the scope of the present teachings.

Referring to FIG. 3F, a desired number of additional functional prepreg material layers, primer layers and corresponding metal layers (patterned or non-patterned) are applied. In the depicted example, the second layer of functional prepreg material 132 is applied over the first patterned metal layer 113 and the third primer layer 123. The fourth primer layer 124 is applied to a top surface of the second layer of functional prepreg material 132. The second layer of functional prepreg material 132 and preformed sheet 200 are stacked, and the structure goes through hot press lamination. The primer layer 204 is peeled, and the primer coated metal layer 203 is etched out to provide the fourth primer layer 124 for forming patterning. The second patterned metal layer 114 is formed on the fourth primer layer 124 using a patterning and etching process, as discussed above. Further, in the depicted example, the third layer of functional prepreg material 133 is applied over the second patterned metal layer 114 and the fourth primer layer 124, and the second primer layer 122 is applied to a top surface of the third layer of functional prepreg material 133, e.g., using the illustrative processes discussed above. The second outer metal layer 112 is formed by stacking the third layer of functional prepreg material 133 and the preformed sheet 200 and applying a hot press lamination process step.

As shown in FIG. 3G, the detachable core 301, the layer of non-functional prepreg material 308 and the first carrier metal layer 101 are removed from the first outer metal layer 111, exposing the first outer metal layer 111. For example, the first carrier metal layer 101 may be peeled away from the first outer metal layer 111 via the first release layer 102, exposing the first outer metal layer 111. Removing the first carrier metal layer 101 may include a decarrier or depanel process, mentioned above. Thus, the first outer metal layer 111 provides the first (bottom) outer most surface of the coreless substrate 100, while the second outer metal layer 112 provides the second (top) outer most surface of the coreless substrate 100. Notably, as a result of the process, the coreless substrate 100 is the same in both FIGS. 1 and 3G.

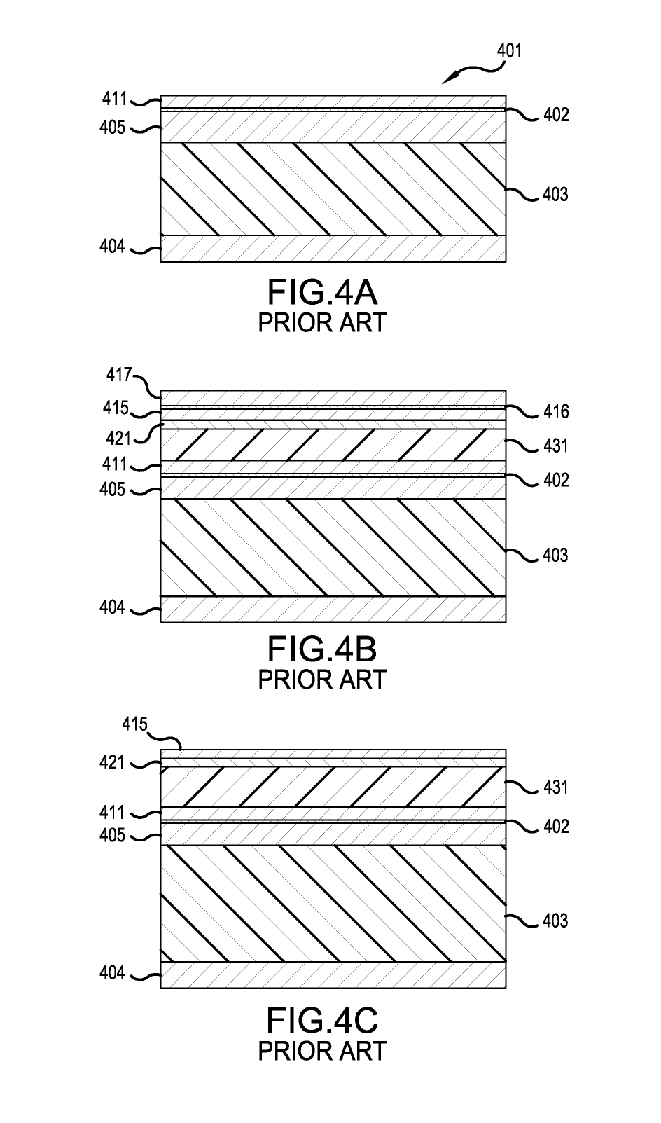

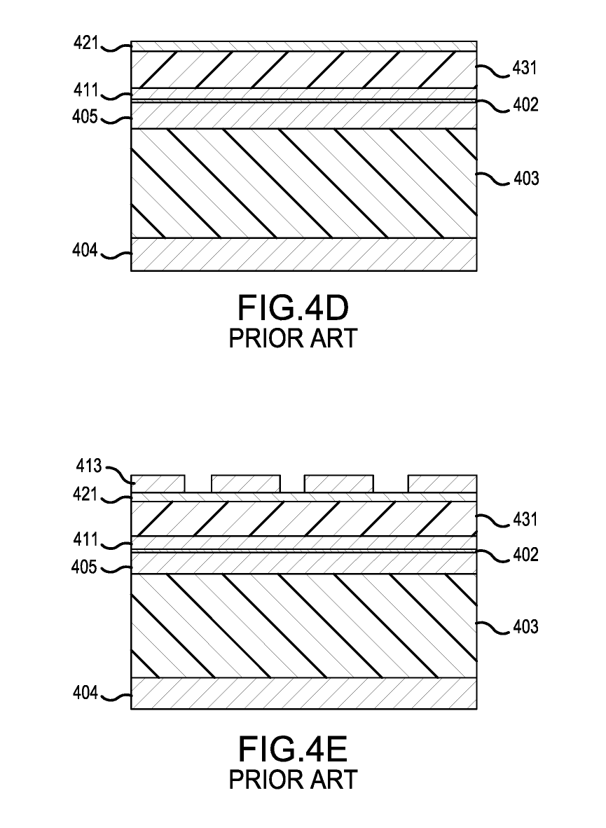

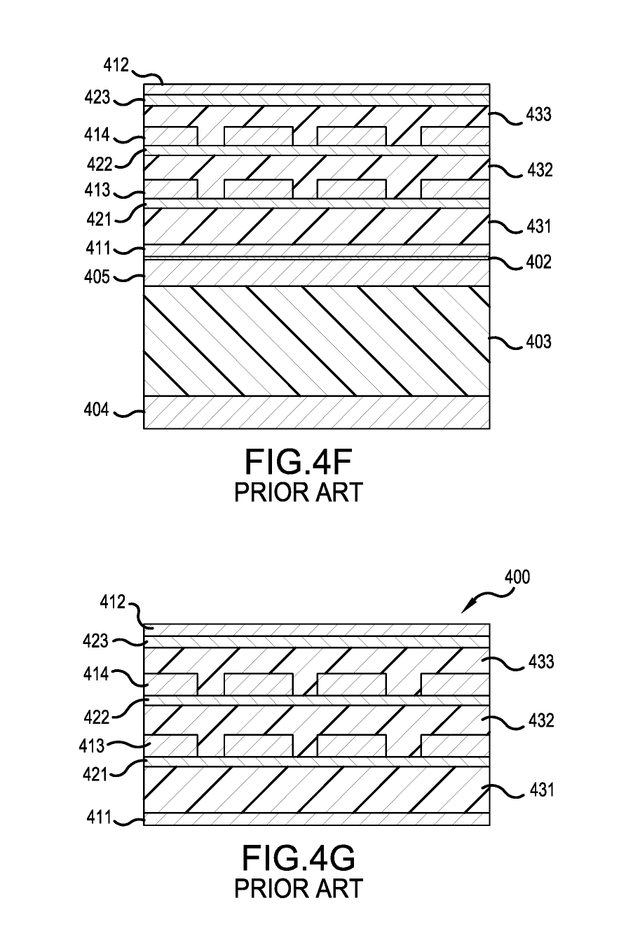

For purposed of comparison, FIGS. 4A to 4G are provided, which depict simplified cross-sectional views showing a conventional method of fabricating a conventional multi-layer coreless substrate of a PCB. As shown in FIG. 4G, the end result is a coreless substrate 400 that includes a first outer metal layer 411, but no first primer layer adjacent to the first outer metal layer 411. Therefore, continuation of a symmetric build-up on the bottom outer most surface of the coreless substrate 400 (i.e., in addition to build-up on the top outer most surface of the coreless substrate 400) is not possible due to the unavailability of a first primer layer on the first outer metal layer 411. That is, there is no paired outer metal layer and primer layer at the bottom outer most surface of the coreless substrate 400, but only a paired outer metal layer and primer layer at the top outer most surface of the coreless substrate 400.

Referring to FIG. 4A, a detachable core 401 is provided. The detachable core 401 comprises a dummy organic core layer 403 between first and second copper layers 404 and 405. A first release layer 402 and a first outer metal layer 411 are stacked on the second copper layer 405.

In FIG. 4B, an initial stack-up is formed on the first outer metal layer 411 for lamination. More particularly, a first layer of functional prepreg material 431 is applied to the first outer metal layer 411, and a first primer layer 421, a temporary metal layer 415, a second release layer 416 and a carrier metal layer 417 are stacked on the first layer of functional prepreg material 431. As discussed above, the stack including the first primer layer 421, the temporary metal layer 415, the second release layer 416 and the carrier metal layer 417 may be implemented, for example, using the preformed sheet 200 (inverted) depicted in FIG. 2.

The carrier metal layer 417 is peeled away via the second release layer 416, as shown in FIG. 4C, exposing the temporary metal layer 415. The temporary metal layer 415 is then removed, as shown in FIG. 4D, exposing the first primer layer 421. In FIG. 4E, a first patterned metal layer 413 is formed on the exposed first primer layer 421, e.g., by applying a metal layer to the first primer layer 421, and patterning and etching the applied metal layer to form the first patterned metal layer 413.

Referring to FIG. 4F, a desired number of additional functional prepreg material layers, primer layers and corresponding metal layers (patterned or non-patterned) are applied. In the depicted example, the second layer of functional prepreg material 432 is applied over the first patterned metal layer 413 and the first primer layer 421. A second primer layer 422 is applied to a top surface of the second layer of functional prepreg material 432, and a second patterned metal layer 414 is formed on the second primer layer 422 using a patterning and etching process, as discussed above. A third layer of functional prepreg material 433 is applied over the second patterned metal layer 414 and the second primer layer 422, and a third primer layer 423 is applied to a top surface of the third layer of functional prepreg material 433, e.g., using the illustrative processes discussed above. The second outer metal layer 412 is applied to the third primer layer 423.

As shown in FIG. 4G, the detachable core 401 is removed from the first outer metal layer 411, exposing the first outer metal layer 411. For example, the first copper layer 405 may be peeled away from the first outer metal layer 411 via the first release layer 402, exposing the first outer metal layer 411. Thus, the first outer metal layer 411 provides the first (bottom) outer most surface of the coreless substrate 400, while the second outer metal layer 412 provides the second (top) outer most surface of the coreless substrate 400. However, as mentioned above, there is no first primer layer adjacent to the first outer metal layer 411. Therefore, continuation of a symmetric build-up on the bottom outer most surface of the coreless substrate 400 (i.e., in addition to build-up on the top outer most surface of the coreless substrate 400 is not possible due to the unavailability of the first primer layer on the first outer metal layer 411.

The various components, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

What is claimed:

1. A coreless substrate of a printed circuit board, the coreless substrate comprising:
a first outer metal layer corresponding to a first outer most surface of the coreless printed circuit board, post detach process;
a first primer layer formed on the first outer metal layer;
a first layer of functional prepreg material formed on the first primer layer;
a second primer layer formed over the first layer of functional prepreg material; and
a second outer metal layer formed on the second primer layer, the second outer metal layer corresponding to a second outer most surface of the printed circuit board.

2. The coreless substrate of claim 1, wherein the first and second outer most surfaces of the printed circuit board are symmetric.

3. The coreless substrate of claim 1, wherein each of the first and second outer metal layers comprises copper foil.

4. The coreless substrate of claim 3, wherein each of the first and second outer metal layers has a thickness in a range of approximately 5 μm to approximately 20 μm.

5. The coreless substrate of claim 3, wherein each of the first and second primer layers comprises epoxy resin.

6. The coreless substrate of claim 1, wherein a surface of the first outer metal layer contacting the first primer layer is smoother than an opposite surface of the first outer metal layer.

7. The coreless substrate of claim 1, further comprising:
an intermediate primer layer formed on the first layer of functional prepreg material;
a patterned metal layer formed on the intermediate primer layer; and
a second layer of functional prepreg material formed on the patterned metal layer,
wherein the second primer layer is formed over the first and second layers of functional prepreg material.

8. The coreless substrate of claim 7, where each of the first layer of functional prepreg material and the second layer of functional prepreg material provides structural support and electrical isolation.

9. A coreless substrate of a laminated printed circuit board, the coreless substrate comprising:
a first outer metal layer providing a first outer most surface of the printed circuit board;
a first primer layer disposed adjacent to the first outer metal layer;
a first layer of functional prepreg material disposed adjacent to the first primer layer;
a second outer metal layer providing a second outer most surface of the printed circuit board, opposite the first outer most surface;
a second primer layer disposed adjacent to the second outer metal layer;
a second layer of functional prepreg material disposed adjacent to the second primer layer; and
at least one buried patterned metal layer and a corresponding at least one buried intermediate primer layer positioned between the first and second layers of the functional prepreg material.

10. The coreless substrate of claim 9, wherein each of the first and second outer metal layers and the at least one buried patterned metal layer comprises copper.

11. The coreless substrate of claim 10, wherein each of the first and second outer metal layers has a thickness in a range of approximately 5 μm to approximately 20 μm.

12. The coreless substrate of claim 10, wherein each of the first and second primer layers and the at least one buried intermediate primer layer comprises epoxy resin.

13. The coreless substrate of claim 9, wherein a surface of the first outer metal layer contacting the first primer layer is smoother than an opposite surface of the first outer metal layer.

14. The coreless substrate of claim 9, where each of the first layer of functional prepreg material and the second layer of functional prepreg material provides structural support and electrical isolation.

15. A method of fabricating a coreless substrate, the method comprising:
providing an organic carrier layer;
applying a layer of non-functional prepreg material to the organic carrier layer;
applying a stack of a first carrier metal layer, a first release layer, a first metal layer, and a first primer layer to the layer of non-functional prepreg material;
applying a first layer of functional prepreg material to the first primer layer;
applying an inverted stack of a second carrier metal layer, a second release layer, a second metal layer and a second primer layer to the first layer of functional prepreg material;
removing the second carrier metal layer and the release layer from the inverted stack;
removing the second metal layer to expose the second primer layer;
applying a metal layer to the exposed second primer layer, and patterning the metal layer to form a first patterned metal layer;
applying a second layer of functional prepreg material over the first patterned metal layer;
applying a third primer layer over the second layer of functional prepreg material;
applying a third metal layer on the third primer layer; and
removing the organic carrier layer, the layer of non-functional prepreg material, the first carrier layer and the first release layer from the first metal layer, resulting in the first metal layer and the third metal layer being outer most surfaces of the coreless substrate, respectively.

16. The method of claim 15, wherein the organic carrier layer comprises copper clad laminate.

17. The method of claim 16, wherein the non-functional prepreg material comprises a dielectric material.

18. The method of claim 15, wherein removing the second carrier metal layer and the release layer from the inverted stack comprises a decarrier or depanel process.

19. The method of claim 15, wherein removing the second metal layer to expose the second primer layer comprises a chemical etching process.
